(19) United States
(12) Patent Application Publication
(10) Pub. No.: US 2026/0358538 A1
(43) Pub. Date: Nov. 12, 2026

(54) APPARATUS FOR MANUFACTURING AT LEAST TWO DIFFRACTIVE OPTICAL ELEMENTS AND METHOD FOR MANUFACTURING AT LEAST TWO DIFFRACTIVE OPTICAL ELEMENTS

(71) Applicant: AlphaLum SA, Lausanne (CH)

(72) Inventors: Carlos Macias, Pully (CH); Robin Kaech, Lausanne (CH)

(21) Appl. No.: 19/123,011

(22) PCT Filed: Oct. 18, 2023
(86) PCT No.: PCT/EP2023/078930

§ 371 Date: Apr. 21, 2025

(30) Foreign Application Priority Data
Oct. 26, 2022 (DE) 10 2022 128 337.2

(51) Int. Cl. G02B 5/18; G03F 7/00

(52) U.S. Cl. CPC G02B 5/1857; G03F 7/0005; G03F 7/70025; G03F 7/70041; G03F 7/70066; G03F 7/70275; G03F 7/70308; G03F 7/70316; G03F 7/704; G03F 7/7055

(57) ABSTRACT

In an embodiment an apparatus includes a light source configured for emitting electromagnetic laser radiation, a phase modulator configured for imparting a phase profile on the electromagnetic laser radiation, a beam steering unit configured for directing the electromagnetic laser radiation on different locations of the phase modulator, during a scanning time interval and a synchronization unit configured for synchronizing a generation of object beam pulses and reference beam pulses with the beam steering unit such that no object beam pulses and no reference beam pulses form interference patterns on a photosensitive plate during the scanning time interval, wherein the scanning time interval is at most 10 millisecond, and wherein the photosensitive plate comprises a photosensitive material with a chemical reaction time interval larger than a cycle time interval, the cycle time interval comprising the scanning time interval and an recordation time interval.

### CROSS-REFERENCE TO RELATED APPLICATIONS

This patent application is a national phase filing under section 371 of PCT/EP2023/078930, filed Oct. 18, 2023, which claims the priority of German patent application no. 102022128337.2, filed Oct. 26, 2022, each of which is incorporated herein by reference in its entirety.

### TECHNICAL FIELD

An apparatus for manufacturing at least two diffractive optical elements and a method for manufacturing at least two diffractive optical elements are provided.

### SUMMARY

Embodiments provide an apparatus for manufacturing at least two diffractive optical elements. Other embodiments provide a method for manufacturing at least two diffractive optical elements.

According to an embodiment, the apparatus comprises a light source configured for emitting electromagnetic laser radiation. For example, the light source is a laser, such as a laser diode or a solid state laser. For example, a single frequency laser is used as light source. For example, the electromagnetic laser radiation has a wavelength between and including 400 nanometer and 700 nanometer. A coherence length of the electromagnetic laser radiation is particularly preferably between 200 micrometer and 50 centimeter. A power of the laser is for example between 0.5 mW/cm² and 20 mW/cm², limits inclusive.

For example, the apparatus comprises more than one laser emitting electromagnetic laser radiation of different wavelengths. The electromagnetic laser radiation of different wavelength is, particularly, combined to a single beam of electromagnetic laser radiation, for example by a combiner box. For example, three lasers are used, one laser emitting electromagnetic laser radiation with a wavelength of about 450 nanometer, one laser emitting electromagnetic laser radiation with a wavelength of about 520 nanometer and one laser emitting electromagnetic laser radiation with a wavelength of about 640 nanometer.

According to a further embodiment, the apparatus comprises a phase modulator configured for imparting a phase profile on the electromagnetic laser radiation. In particular, the phase modulator imparts a phase profile on the electromagnetic laser radiation during operation. For example, the phase modulator imparts phase profiles on object beam pulses generated from the electromagnetic laser radiation, the phase profiles being different from each other. Further, it is possible that the phase modulator imparts the same phase profiles on at least some of the object beam pulses.

According to a further embodiment, the apparatus comprises a beam steering unit configured for directing the electromagnetic laser radiation on different locations of the phase modulator. Particularly, the beam steering unit directs the electromagnetic laser radiation on different locations of the phase modulator during operation. Particularly preferably, the beam steering unit directs the electromagnetic laser radiation on different locations of the phase modulator arranged in a same virtual plane. In other words, the beam steering unit has a two-dimensional scanning function. For example, the beam steering unit directs the electromagnetic laser radiation in a first step on a location (x,y) of the virtual plane and in a second step on a further location (x′,y)′ different from the first location (x,y). Particularly, the virtual plane is located on or within the phase modulator. Particularly, the virtual plane is perpendicular to an optical axis of the apparatus.

According to a further embodiment, the apparatus comprises a synchronization unit configured for synchronizing a generation of object beam pulses and reference beam pulses with the beam steering unit such that no object beam pulses and no reference beam pulses form interference patterns on a photosensitive plate during a scanning time interval. The beam pulses have a beam length. Further, two directly successive beam pulses have a time distance.

For example, the object beam pulses and the reference beam pulses are generated during operation by a chopper unit. Particularly, the chopper unit blocks the electromagnetic laser radiation during a blocking time interval and transmits the electromagnetic laser radiation during a passing time interval. In such a way, beam pulses are generated from the electromagnetic laser radiation. In other words, the chopper unit generates beam pulses separated from each other in time from the electromagnetic laser radiation. Particularly, a beam length of the beam pulses equals the passing time interval.

It is also possible that the beam pulses are generated by the light source. If the light source is a laser, the laser is, for example, modulated according to an embodiment in order to generate beam pulses. In that case the apparatus is particularly free of a chopper unit.

According to a further embodiment of the apparatus, the scanning time interval is at most 10 millisecond. Consequently, the scanning frequency of the beam steering unit is at least 0.1 kHz. Particularly, the beam steering unit directs the electromagnetic laser radiation with the scanning frequency on two different locations on the phase modulator.

According to a further embodiment of the apparatus, the apparatus comprises a chopper unit configured for blocking the electromagnetic laser radiation during a blocking time interval and transmitting the continuous beam of electromagnetic laser radiation during a passing time interval such that beam pulses are generated from the electromagnetic laser radiation. The chopper unit particularly blocks the electromagnetic laser radiation during the blocking time interval and transmits the electromagnetic laser radiation during the passing time interval such that beam pulses are generated from the continuous beam of electromagnetic laser radiation. In other words, the chopper unit generates beam pulses separated from each other in time from the electromagnetic laser radiation. Particularly, a beam length of the beam pulses equals the passing time interval. The beam length of the beam pulses is, for example, at most 10milliseconds. The time distance between two directly successive beams pulses equals the blocking time interval. The time distance between two directly successive beams pulses is for example, between and including ½ and 1/100 of the beam length. In particular, the chopper unit is a mechanical chopper unit or a digital chopper unit.

According to a further embodiment, the apparatus comprises an optical splitting element configured for splitting the electromagnetic laser radiation into object laser radiation and reference laser radiation. In other words, the optical splitting element splits the electromagnetic laser radiation into object laser radiation and reference laser radiation during operation. Particularly, the splitting of the electromagnetic laser radiation takes place in a spatial manner. In other words, the object laser radiation passes a different optical beam path than the reference laser radiation. Particularly, the optical beam path of the object laser radiation and the optical beam path of the reference laser radiation have the same optical length.

The chopper unit generating beam pulses during operation can be arranged before or after the optical splitting element. For example, the chopper unit for generating beam pulses from the electromagnetic laser radiation is arranged between the light source and the optical splitting element. In this case, the electromagnetic laser radiation is at first separated in a plurality of beam pulses by the chopper unit and then split in object beam pulses of object laser radiation and in reference beam pulses of reference laser radiation.

It is also possible that the beam pulses are generated after the splitting element during operation. In that case, the splitting element splits the electromagnetic laser radiation in object laser radiation and reference laser radiation at first. Further, the apparatus comprises in that case at least two chopper units, one chopper unit being arranged in the optical beam path of the reference laser radiation generating reference beam pulses and one chopper unit being arranged in the optical beam path of the object laser radiation generating object laser radiation. If the apparatus comprises more than one chopper unit, the chopper units are also synchronized by the synchronization unit, in particular.

Particularly, the optical beam path of the object laser radiation and the optical beam path of the reference laser radiation have the same optical length between the optical splitting element and the photosensitive plate, independently from the location of beam pulse generation.

If the apparatus comprises a chopper unit arranged between the light source and the optical splitting element, the synchronization unit is preferably configured for synchronizing the chopper unit and the beam steering unit such that the chopper unit blocks the electromagnetic laser radiation during the scanning time interval, the beam steering unit directing two successive object beam pulses on different locations of the phase modulator during the scanning time interval. In other words, the synchronization unit synchronizes the chopper unit and the beam steering unit during operation such that the chopper unit blocks the continuous beam of electromagnetic laser radiation during the scanning time interval, wherein the beam steering unit directs two successive object beam pulses on different locations of the phase modulator during the scanning time interval. By the help of the synchronization unit, no beam pulse is generated by the chopper unit when the beam steering unit changes the location of the object beam pulses on the phase modulator.

According to a further embodiment of the apparatus, the scanning time interval comprises or consists of an active scanning time interval and a settling time interval. During the active scanning time interval the beam steering unit is driven, for example by a voltage signal, and during the settling time interval the beam steering unit equilibrates in an equilibrium state. It is clear for a person skilled in the art that the equilibrium state can never be achieved in reality. However, the beam steering unit equilibrates during the settling time interval as far as no change in its state disturbs the function of the apparatus.

In particular, the settling time interval is at most 100 microsecond. Particularly, the blocking time interval is at least as long as the scanning time interval, if a chopper unit is used for generating beam pulses. In particular, the time distance between two directly successive beam pulses is at least as long as the scanning time interval. In particular, the time distance between two directly successive object beam pulses and/or the time distance between two directly successive reference beam pulses is at least as long as the scanning time interval.

According to a further embodiment of the apparatus, the phase modulator also acts dynamically. For example, the phase modulator changes its optical function, particularly the phase profile to be imparted on the electromagnetic laser radiation, as the beam steering unit also during the scanning time interval. If this is the case, the synchronization unit is configured for also synchronizing the phase modulator with the beam steering unit and the generation of beam pulses. In other words, in this case the synchronization unit synchronizes not only the beam steering unit with the generation of the beam pulses, but also the phase modulator with the beam steering unit. If the apparatus comprises at least one chopper unit, the synchronization unit synchronizes the phase modulator, the beam steering unit and all chopper units.

According to a further embodiment, the photosensitive plate is configured for recording interference patterns of the object beam pulses and the reference beam pulses. In other words, the photosensitive plate records the interference patterns of the object beam pulses and the reference beam pulses during operation of the apparatus.

Particularly, the object laser radiation and the reference laser radiation run on spatially different optical beam paths, wherein the reference laser radiation do not impinge on the phase modulator and is not phase modulated by the phase modulator. Directly before the photosensitive plate, object beam pulses phase modulated by the phase modulator and references beam pulses are present. The phase object beam pulses phase modulated by the phase modulator and the reference beam pulses are superimposed in a plane of the photosensitive plate and form interference patterns on the photosensitive plate, since the object beam pulses phase modulated by the phase modulator and the reference beam pulses still have a phase relation to each other. In particular, different interference patterns interact with each other, since they are created by superimposing reference beam pulses from the same electromagnetic laser radiation with object beam pulses phase modulated by the phase modulator. For example, the interference patterns overlap at least partially with each other on the photosensitive plate.

Particularly, recording the interference pattern takes place during the duration of the beam pulses. The duration of the beam pulses, which corresponds to the beam length, equals a recordation time interval. If the apparatus comprises a chopper unit, the duration of the object beam pulses equals the passing time interval of the chopper unit. In other words, a recordation time interval of the interference patterns equals the passing time interval of the chopper unit.

According to a further embodiment of the apparatus, the photosensitive plate comprises a photosensitive material having a chemical reaction time interval larger than a cycle time interval, the cycle time interval comprising or consisting of the scanning time interval and the recordation time interval. In other words, the chemical reaction time interval of the photosensitive material is larger than the sum of the scanning time interval and the recordation time interval.

Since the time distance between two directly succesive beam pulses is at least as long as the scanning time interval and the recordation time equals the time distance between two directly succesive beam pulses, the cycle time interval equals particularly the time interval between the beginning of two directly succesive beam pulses. Therefore, if the chemical reaction time interval of the photosensitive material (including a diffusion time of the chemical components) is larger than the cycle time, the photosensitive material “sees” a continious exposure. Therefore, the diffractive optical elements can be multiplexed in a quasi-simultaneous manner. In contrast to a simultaneous approach restricted to recordation of interference patterns not interacting with each other, with the present quasi-simultaneous approach also interference patterns can be recorded interacting with each other. Further, the present quasi-simultaneous approach avoids the disadvantage of a sequential approach, namely the need of a complicated recording schedule.

For example, the photosensitive material comprises monomers of a photopolymer, the monomers diffusing towards zones of high intensity and polymerizing during the chemical reaction time interval when exposed by the interference pattern. In such a way the interference pattern is recorded. In other words, the monomers of the photosensitive material agglomerate and polymerize due to the exposure with the interference patterns generated by superimposing the phase modulated object beam pulses and the reference beam pulses.

According to a further embodiment, the apparatus comprises a beam steering unit comprising one of the following elements directing the object beam pulses on different locations of the phase modulator: a two-dimensional mirror galvanometer, a two-dimensional optical phased array (short: “OPA”), a digital light processing element (short: “DLP”), and acousto optical modulator (short “AOM”). Particularly, the two-dimensional mirror galvanometer is formed by two mirror galvanometers.

According to a further embodiment of the apparatus, the phase modulator comprises or consists of a micro lens array configured for imparting the phase profile on the electromagnetic laser radiation. In other words, the micro lens array imparts the phase profile on the electromagnetic laser radiation during operation.

According to a further embodiment, the apparatus further comprises one or more optical elements with a splitting function, a magnifying function, a de-magnifying function, a relaying function and/or an imaging function.

According to a further embodiment of the apparatus, the beam steering unit comprises or consists of two mirror galvanometers forming a two-dimensional scanner unit, the two mirror galvanometers being arranged within a focus plane of a telescope. For example, the telescope comprises or consists of two collector lenses, wherein the focus plane of the telescope is arranged there between.

According to a further embodiment of the apparatus, the beam steering unit comprises or consists of a two-dimensional optical phased array forming the two-dimensional scanner unit, the two-dimensional optical phased array being arranged within the focus plane of the telescope.

According to a further embodiment of the apparatus, the beam steering unit comprises or consists of a digital light processing element, the phase modulator comprises or consist of a micro lens array and the digital light processing element is imaged and magnified on the micro lens array during operation.

With the apparatus, at least two diffractive optical elements are manufactured at the same time on the same photosensitive plate during operation. In other words, the at least two diffractive optical elements are multiplexed. If more than one laser is used, wavelength multiplexing can be performed. Particularly preferably, a plurality of diffractive optical elements are manufactured at the same time on the same photosensitive plate during operation.

In the following a method for manufacturing at least two diffractive optical elements is described, particularly with the use of the disclosed apparatus. Therefore, features and embodiments disclosed in connection with the apparatus are also valid for the method and vice versa.

According to an embodiment of the method for manufacturing at least two diffractive optical elements, electromagnetic laser radiation is provided.

According to a further embodiment of the method, the electromagnetic laser radiation is directed on different locations of a phase modulator with a beam steering unit during a scanning time interval.

According to a further embodiment of the method, a phase profile is imparted on the electromagnetic laser radiation with a phase modulator.

According to a further embodiment of the method, a generation of object beam pulses and reference beam pulses with the beam steering unit is synchronized by a synchronization unit such that no object beam pulses and no reference beam pulses form interference patterns on a photosensitive plate during the scanning time interval.

According to a further embodiment of the method, the beam steering unit changes the location of the electromagnetic laser radiation on the phase modulator during the scanning time interval, the scanning time interval being at most 10 millisecond.

According to a further embodiment of the method, the electromagnetic laser radiation is blocked during a blocking time interval and transmitted during a passing time interval by a chopper unit such that beam pulses are generated from the electromagnetic laser radiation.

According to a further embodiment of the method, the electromagnetic laser radiation is split into object laser radiation and reference laser radiation with an optical splitting element. Splitting takes place in a spatial manner such that the object laser radiation and the reference laser radiation run on different optical beam paths.

According to a further embodiment of the method, the generation of the beam pulses and the beam steering unit are synchronized by a synchronization unit such that no beam pulses are generated during the scanning time interval. If a chopper unit is used for the generation of the beam pulses, the chopper unit and the beam steering unit are synchronized by the synchronization unit such that the chopper unit blocks the electromagnetic laser radiation during the scanning time interval.

According to an embodiment, the method comprising the steps:
providing the electromagnetic laser radiation,
directing the electromagnetic laser radiation on different locations of the phase modulator with the beam steering unit during the scanning time interval,
imparting the phase profile on the electromagnetic laser radiation with the phase modulator, and
synchronizing a generation of the object beam pulses and the reference beam pulses with the beam steering unit by a synchronization unit such that no object beam pulses and no reference beam pulses form interference patterns on the photosensitive plate during the scanning time interval,
wherein the scanning time interval is at most 10 millisecond.

According to a further embodiment of the method, object beam pulses phase modulated by the phase modulator are superimposed with the reference beam pulses such that a plurality of interference patterns is created. Particularly, the interference patterns are recorded on the photosensitive plate.

According to a further embodiment of the method, at least two of the interference patterns spatially overlap with each other on the photosensitive plate at least partially.

According to a further embodiment, the method further comprises the step of finishing the at least two diffractive optical elements, wherein at least one interference pattern is comprised by one diffractive optical element.

Particularly, finishing the at least two diffractive optical elements can comprise developing the photosensitive material on the photosensitive plate and/or dividing the photosensitive plate in different diffractive optical elements. The diffractive elements can be arranged entirely or partially overlapping or completely distinct from each other in the photosensitive plate.

For example, the diffractive optical element is a hologram. Particularly, the phase information provided by the phase modulator and imparted on the object laser radiation is stored by the diffractive optical element.

The diffractive optical element manufactured with the apparatus and/or the method can be an optical combiner, an optical filter or an optical splitter. For example, the diffractive optical element is used in augmented reality applications or virtual reality applications.

With the apparatus and/or the method a large number of diffractive optical elements, for example holograms, can be multiplexed on a single photosensitive plate with better quality compared to existing methods due to the quasi-simultaneous approach.

Particularly, the apparatus and the method take advantage of the slow chemical response time interval of the photosensitive material such that, from the point of view of the photosensitive material, the recording is done simultaneously while avoiding interaction between multiplexed diffractive optical elements. It is particularly possible with the apparatus and the method to record two-dimensional diffractive elements without a recording schedule, the recording schedule comprises information about the recording exposure time that each one of the diffractive elements would require such that they all have a given (or the same) diffraction efficiency.

Particularly, the recording of the interference patterns of the diffractive optical elements can be performed with the apparatus and the method with enhanced speed. Particularly, the optical functions of the phase profiles to be multiplexed are cycled through at very high speeds using a beam steering device with high scanning frequency.

### BRIEF DESCRIPTION OF THE DRAWINGS

Further advantageous embodiments and developments of the apparatus and the method result from the exemplary embodiment described below in connection with the Figures.

FIG. 1 shows a schematic view of an apparatus for manufacturing at least two diffractive optical elements according to an exemplary embodiment;

FIG. 2 shows schematically a flow diagram of a method for manufacturing at least two diffractive optical elements according to an exemplary embodiment;

FIG. 3 shows schematically a stage of the method according to the exemplary embodiment of FIG. 2;

FIG. 4 shows schematically different time intervals of the method according to the exemplary embodiment of FIG. 2;

FIG. 5 shows schematically voltage signals for driving a beam steering unit of an apparatus for manufacturing at least two diffractive optical elements according to an exemplary embodiment;

FIGS. 6 and 7 show schematically excerpts of apparatuses for manufacturing at least two diffractive optical elements according to two further exemplary embodiments;

FIGS. 8 and 9 show schematic views of an apparatus for manufacturing at least two diffractive optical elements according to further exemplary embodiments; and

FIG. 10 shows a light source according to an exemplary embodiment.

### DETAILED DESCRIPTION OF ILLUSTRATIVE EMBODIMENTS

Equal or similar elements as well as elements of equal function are designated with the same reference signs in the Figures. The Figures and the proportions of the elements shown in the Figures are not regarded as being shown to scale. Rather, single elements, in particular layers, can be shown exaggerated in magnitude for the sake of better presentation and/or better understanding.

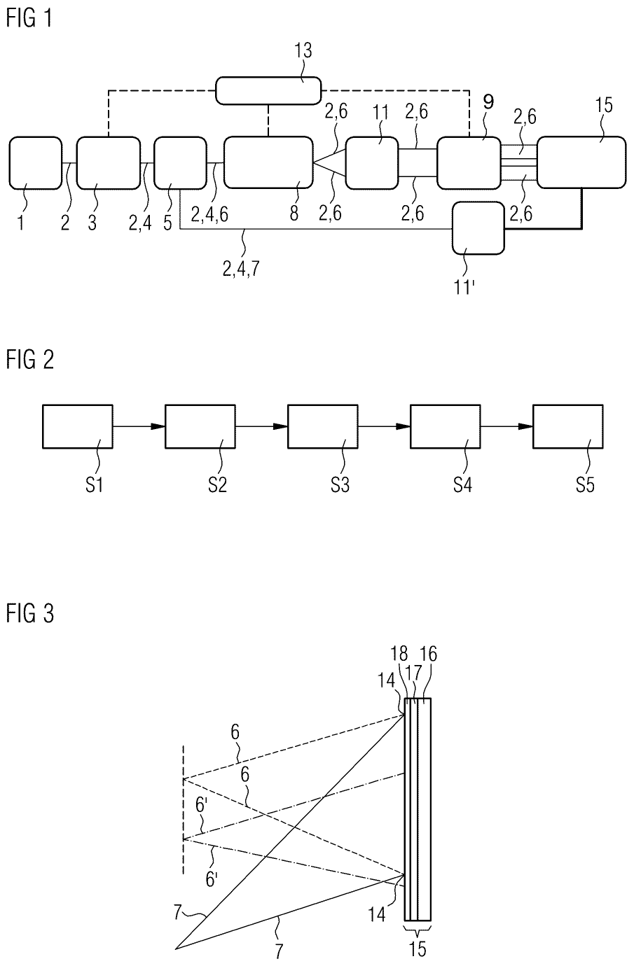

The apparatus according to the exemplary embodiment of FIG. 1 comprises a laser as a light source 1 emitting electromagnetic laser radiation 2 during operation.

The apparatus of FIG. 1 further comprises a chopper unit 3, which is arranged after the light source 1. The electromagnetic laser radiation 2 emitted by the light source 1 impinges on the chopper unit 3. The chopper unit 3 blocks the electromagnetic laser radiation 2 emitted by the light source 1 during a blocking time interval Δt_{block} and transmits the electromagnetic laser radiation during a passing time interval Δtₚₐₛₛ. In such a way beam pulses 4 are generated from the electromagnetic laser radiation 2.

The beam pulses 4 impinge on an optical splitting element 5 arranged after the chopper unit 3. The optical splitting element 5 splits the beam pulses 4 into object beam pulses 6 of object laser radiation and reference beam pulses 7 of reference laser radiation. Splitting takes place in a spatial manner so that the reference beam pulses 7 run through a different optical path than the object beam pulses 6.

Further, the apparatus of FIG. 1 comprises a beam steering unit 8, the beam steering unit 8 directs the object beam pulses 6 on different locations of a virtual two-dimensional plane lying on or within a phase modulator 9. A scanning time interval Δt_{scan} between two different positions of two directly successive object beam pules 6 is at most 10 milliseconds. The phase modulator 9 imparts one or several phase profiles on the object beam pulses 6 such that object beam pulses 6 modulated by the phase modulator 9 are generated. The phase modulator 9, for example a phase array or a micro lens array, also changes its optical function during the scanning time interval Δt_{scan}.

Particularly, the reference beam pulses 7 do not pass the phase modulator 9 and are therefore not phase modulated by the phase modulator 9.

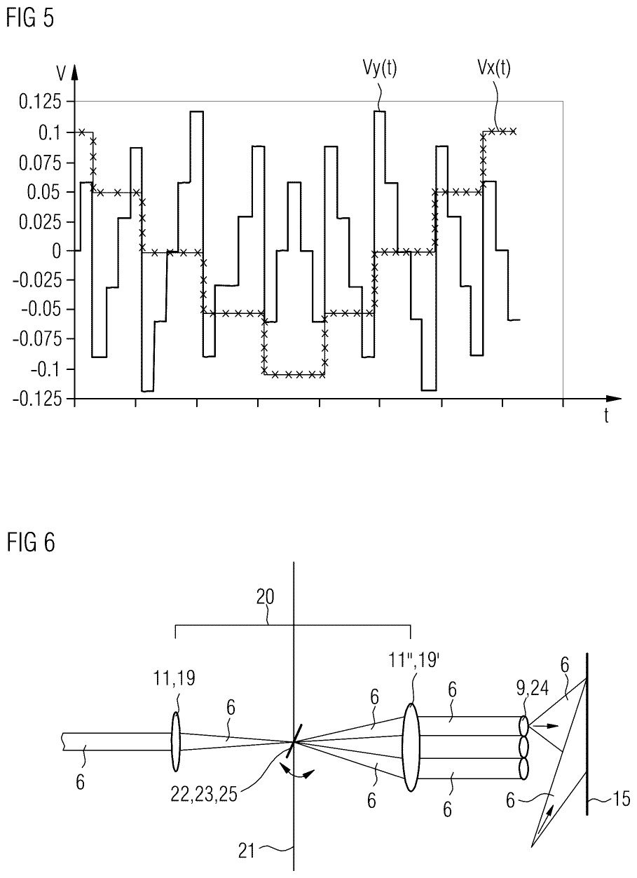

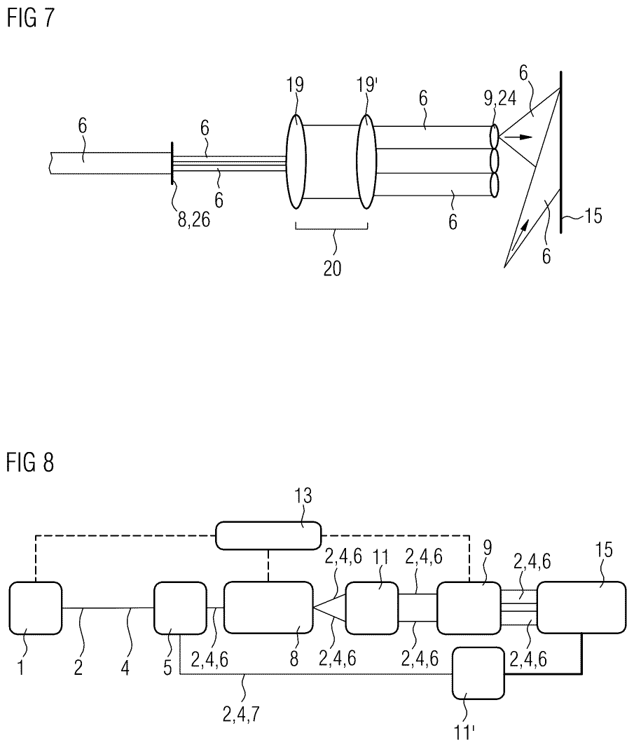

At present, a further optical element 11 is arranged between the beam steering unit 8 and the phase modulator 9. The further optical element 11 is, for example, part of a telescope 20 as described in connection with FIGS. 6 and 7.

At present, the chopper unit 3, the beam steering unit 8 and the phase modulator 9 are synchronized with each other by a synchronization unit 13. Particularly, the synchronization unit 13 ensures that the chopper unit 3 blocks the continuous beam 2 of electromagnetic laser radiation during the scanning time interval Δt_{scan}.

After the phase modulator 9, the object beam pulses 6 modulated by the phase modulator 9 and the reference beam pulses 7 are superimposed in order to generate interference patterns 14 comprising the phase information of the phase modulator 9.

Further, the apparatus of FIG. 1 comprises a photosensitive plate 15 with a main extension surface onto which the object beam pulses 10 phase modulated by the phase modulator 9 and the reference beam pulses 7 interfere and form the interference patterns 14. The interference patterns 14 expose the photosensitive plate 15 such that the interference patterns 14 and thus the phase information of the phase modulator 9 is recorded by the photosensitive plate 15.

In the optical beam path of the reference beam pulses 7 a further optical element 11′ is arranged, for example for directing the reference beam pulses 7 on the main extension surface of the photosensitive plate 15.

In a first step S1 of the method according to the exemplary embodiment of FIG. 2, electromagnetic laser radiation 2 is provided.

After the step S1 of providing the electromagnetic laser radiation 2, the electromagnetic laser radiation 2 is blocked during a blocking time interval Δt_{block} and transmitted during a passing time interval Δtₚₐₛₛ by a chopper unit 3 such that beam pulses 4 are generated from the continuous beam 2 of electromagnetic laser radiation in a further step S2.

Then, in a third step S3, the beam pulses 4 are split into object beam pulses 6 and reference beam pulses 7 with an optical splitting element 5.

In a further step S4, conducted after the step S3, the object beam pulses 6 are directed on different locations of a phase modulator 9 with a beam steering unit 8. The beam steering unit 8 changes the location of two directly successive object beam pulses 6 on the phase modulator 9 during a scanning time interval Δt_{scan}.

Then, in a step S5, a phase profile is imparted on the object beam pulses 6 with the phase modulator 9.

During the steps S1 to S5, the chopper unit 3 and the beam steering unit 8 are synchronized by a synchronization unit 13 such that the chopper unit 3 blocks the continuous beam 2 of electromagnetic laser radiation during the scanning time interval Δt_{scan}.

FIG. 3 shows the formation of the interference pattern 14 on the photosensitive plate in more detail.

The photosensitive plate 15 comprises a glass carrier 16 onto which a polycarbonate substrate 17 coated with a gel-like photosensitive material 18 is laminated. The gel-like photosensitive material 18 comprises monomers configured for polymerization during exposure with electromagnetic laser radiation.

As shown in FIG. 3, two different object beam pulses 6, 6′ modulated by the phase modulator 9 impinge on a main surface of the photosensitive plate 15 at different locations. The beam pulses 6, 6′ interfere with reference beam pulses 7 in order to form interference patterns 14.

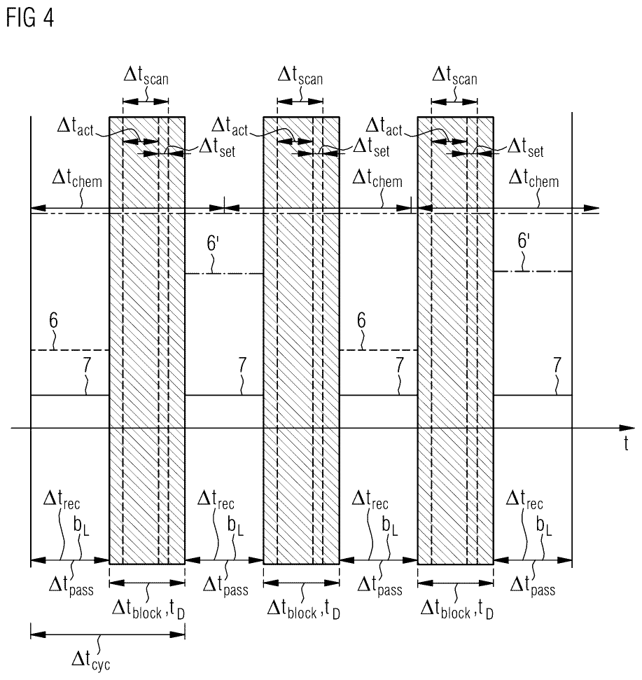

FIG. 4 schematically shows the dependence of the beam pulses 6, 6′ and the reference beam pulses 7 of FIG. 3 on the time t. The chopper unit 3 is closed and blocks the continuous beam 2 of electromagnetic laser radiation during a blocking time interval Δt_{block} (shaded in FIG. 4). During a passing time interval Δtₚₐₛₛ the chopper unit 3 is opened and the light of the continuous beam 2 of electromagnetic laser radiation transmits the chopper unit 3 until the chopper unit 3 is closed again. In such a way beam pulses 4 with a beam length _{bL} of the passing time interval Δtₚₐₛₛ are generated. The reference beam pulses 7, the object beam pulses 6 and the phase modulated object beam pulses 10, 10′ all have the same beam length b_{L}.

In FIG. 4, the blocking time interval Δt_{block} and the passing time interval Δtₚₐₛₛ seem to have a similar duration in order to achieve better viewability. However, the duration of the passing time interval Δtₚₐₛₛ is much higher than the duration of the blocking time interval Δt_{block}. The blocking time interval equals a time distance to between two directly successive beam pulses.

By the help of the synchronization unit 13, the beam steering unit 8 changes the direction of the object beam pulses 6, when the chopper unit 3 is closed during a scanning time interval Δt_{scan}. The scanning time interval Δt_{scan} is composed of an active scanning time interval Δt_{act} and a settling time interval Δtₛₑₜ. During the active scanning time interval Δt_{act}, the beam steering unit 8 is actively driven, for example by voltage signals V(t) as shown in FIG. 5. During the settling time interval Δtₛₑₜ, the beam steering unit 8 settles in an equilibrium state.

The scanning time interval Δt_{scan} is at present smaller than the blocking time interval Δt_{block}. Therefore, recordation of the interference patterns 14 of the object beam pulses 6, 6′ and reference beam pulses 7 on the photosensitive plate 15 only takes place when the beam steering unit 8 and/or the phase modulator 9 are in an equilibrium state. In such a way, the phase information imparted by the phase modulator 9 on the object beam pulses 6 is not disturbed.

If an optical function of the phase modulator 9 is changed between successive object beam pulses 6, this is also done during the blocking time interval Δt_{block} synchronized by the synchronization unit 13 in order to avoid distortion of the interference patterns 14.

When the object beam pulses 6, 6′ phase modulated by the phase modulator 9 and the reference beam pulses 7 interfere on the main surface of the photosensitive plate 15, the photosensitive material 18 of the photosensitive plate 15 is exposed by the interference patterns 14 during the duration of the beam pulses. In other words, recordation of the interference pattern 14 takes place during a recordation time interval Δt_{rec} equally to the beam length b_{L} given by the passing time interval Δtₚₐₛₛ of the chopper unit 3.

At present, a chemical reaction time interval Δt_{chem} of the photosensitive material 18 is larger than a cycle time interval Δt_{cyc} composed of the blocking time interval Δt_{block} and the passing time interval Δtₚₐₛₛ. In particular, the chemical reaction time interval Δt_{chem} of the photosensitive material 18, during that polymerization of the monomers takes place for recording the interference patterns 14, is large enough that the photosensitive material 18 does not detect that the electromagnetic laser radiation is blocked during the blocking time interval Δt_{block}. Therefore, for the photosensitive material 18 the recordation of different interference patterns 14 seems to be simultaneous.

For example, the beam steering unit 8 is driven during the method of the exemplary embodiment of FIG. 2 with voltage signals Vx(t), Vy(t) as shown exemplarily in FIG. 5.

FIG. 5 shows one voltage signal Vx(t) for driving in x-direction and one voltage signal Vy(t) for the y-direction, the x-direction corresponding to the x-axis of the virtual plane of the phase modulator 9 and the y-direction corresponding to the y-axis of the virtual plane of the phase modulator 9. A main characteristic of the driving voltage signals Vx(t), Vy(t) is that they are formed by step functions of different levels such that the diffractive optical element is recorded during the passing time interval Δtₚₐₛₛ.

FIG. 6 shows an excerpt of an apparatus for manufacturing at least two diffractive optical elements according to a further exemplary embodiment.

The apparatus comprises two optical elements 11, 11″, at present two collimating lenses 19, 19′ forming a telescope 20 together. The telescope 20 can have an arbitrary magnification. For example, the first collimating lens 19 is arranged between the optical splitting element 5 and the beam steering unit 8 in the apparatus of FIG. 1, while the second collimating lens 19′ corresponds to the further optical element 11.

The telescope 20 has a focal plane 21, wherein two mirror galvanometers 22 are arranged, the two mirror galvanometers 22 forming a two-dimensional mirror galvanometer 23 as a scanning unit of the beam steering unit 8. The mirror galvanometers 22 particularly move the object beam pulses 6 by rotating a mirror through a galvanometer setup.

Behind the second collimating lens 19′ of the telescope 20, a micro lens array 24 is arranged acting as a phase modulator 9.

The mirror galvanometers 22 within the focal plane 21 of the telescope 20 direct the impinging object beam pulses 6 in a similar direction of propagation and displace them simultaneously. In such a way the object beam pulses 6 illuminate each lens in the micro lens array 24 individually.

Instead of the two mirror galvanometers 22 forming a two-dimensional mirror galvanometer 23 as a scanning unit of the beam steering unit 8, a two-dimensional optical phased array 25 can be arranged in the focal plane 21 of the telescope 20. In that case, the two-dimensional optical phase 25 array forms the scanning unit of the beam steering unit 8.

The apparatus according to the exemplary embodiment of FIG. 7 comprises a digital light processing element 26 as scanning unit of a beam steering unit 8 and a micro lens array 24 as a phase modulator 9. The digital light processing element 26 comprises a plurality of microscopic small mirrors which can be switched electronically and independently from each other.

At present, with the object beam pulses 6 a sequence of binary images, for example masks, is cycled on the digital light processing element 26 by an imaging optical element (not shown) to produce spatially separated object beam pulses 6. The microscopic small mirrors of the digital light processing element 26 deflect the impinging spatially separated object beam pulses 6 or forward them.

A telescope 20 is arranged between the digital light processing element 26 and the micro lens array 24. The telescope 20 comprises at present two collimating lenses 19, 19′. For example, the telescope 20 corresponds to the further optical element 11 of the apparatus of FIG. 1. The digital light processing element 26 is magnified and imaged by the telescope 20 on the micro lens array 24. The micro lenses of the micro lens array 24 are illuminated by the spatially separated object beam pulses 6 one after the other.

The apparatus according to the exemplary embodiment of FIG. 8 is compared to the apparatus of the exemplary embodiment of FIG. 1 free of a chopper unit 3. Instead, the laser representing the light source 1 is modulated such that beam pulses 4 of electromagnetic laser radiation 2 are emitted. The laser is synchronized with a beam steering unit by a synchronization unit (dotted line) such that no beam pulses 4 are generated during a scanning time interval Δt_{scan}. As a consequence, no object beam pulses 6 phase modulated by the phase modulator 9 and reference beam pulses 7 interfere on a photosensitive plate 15 during the scanning time interval Δt_{scan}.

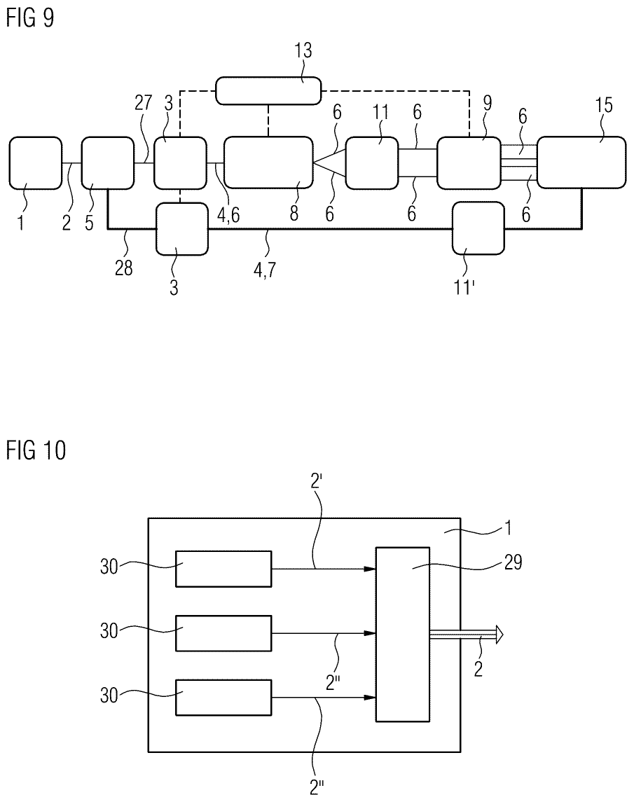

The apparatus according to the exemplary embodiment of FIG. 9 comprises compared to the apparatus of the exemplary embodiment of FIG. 1 two chopper units 3 being arranged after a splitting element 5. The splitting element splits the electromagnetic laser radiation 2 in object laser radiation 27 and reference laser radiation 28. Then the chopper units 3 generate object beam pulses 6 and reference pulses 7. The chopper units 3 are synchronized with a beam steering unit by a synchronization unit (dotted line) such that no beam pulses 4 are generated during a scanning time interval Δt_{scan}. As a consequence, no object beam pulses 6 phase modulated by the phase modulator 9 and reference beam pulses 7 interfere on a photosensitive plate 15 during the scanning time interval Δt_{scan}.

The light source according to the exemplary embodiment of FIG. 10 comprises three different lasers 30 emitting electromagnetic laser radiation of different wavelengths 2′, 2″, 2′″. The electromagnetic laser radiation of different wavelengths 2′, 2″, 2′″ is combined by a combiner box 29 in a single beam of electromagnetic laser radiation 2.

The features and exemplary embodiments described in connection with the Figures can be combined with each other according to further exemplary embodiments, even if not all combinations are explicitly described. Furthermore, the exemplary embodiments described in connection with the Figures may alternatively or additionally have further features according to the description in the general part.

The invention is not limited to the description of the exemplary embodiments. Rather, the invention comprises each new feature as well as each combination of features, particularly each combination of features of the claims, even if the feature or the combination of features itself is not explicitly given in the claims or exemplary embodiments.

1.-18. (canceled)

19. An apparatus for manufacturing at least two diffractive optical elements, the apparatus comprises:
a light source configured for emitting electromagnetic laser radiation;
a phase modulator configured for imparting a phase profile on the electromagnetic laser radiation;
a beam steering unit configured for directing the electromagnetic laser radiation on different locations of the phase modulator, during a scanning time interval; and
a synchronization unit configured for synchronizing a generation of object beam pulses and reference beam pulses with the beam steering unit such that no object beam pulses and no reference beam pulses form interference patterns on a photosensitive plate during the scanning time interval,
wherein the scanning time interval is at most 10 millisecond, and
wherein the photosensitive plate comprises a photosensitive material with a chemical reaction time interval larger than a cycle time interval, the cycle time interval comprising the scanning time interval and an recordation time interval.

20. The apparatus according to claim 19, further comprising a chopper unit configured for blocking the electromagnetic laser radiation during a blocking time interval and transmitting the electromagnetic laser radiation during a passing time interval such that the object beam pulses and the reference beam pulses are generated from the electromagnetic laser radiation.

21. The apparatus according to claim 19,
wherein the scanning time interval comprises an active scanning time interval,
wherein the beam steering unit is driven, and a settling time interval, wherein the beam steering unit equilibrates in an equilibrium state, and
wherein a time distance between two directly successive beam pulses is at least as long as the scanning time interval.

22. The apparatus according to claim 19, wherein the phase modulator is configured for changing its optical function during the scanning time interval.

23. The apparatus according to claim 19, wherein the synchronization unit is configured for also synchronizing the phase modulator with the generation of the beam pulses and the beam steering unit.

24. The apparatus according to claim 19, wherein the photosensitive plate is configured for recording the interference patterns of the object beam pulses and the reference beam pulses during the recordation time interval.

25. The apparatus according to claim 19, wherein the photosensitive material comprises monomers of a photopolymer, the monomers polymerizing during the chemical reaction time interval when exposed by the interference pattern.

26. The apparatus according to claim 19, wherein the beam steering unit comprises one of the following elements directing the object beam pulses on different locations of the phase modulator during operation: a two-dimensional mirror galvanometer, a two-dimensional optical phased array, or a digital light processing element.

27. The apparatus according to claim 19, wherein the phase modulator comprises a micro lens array configured for imparting the phase profile on the electromagnetic laser radiation.

28. The apparatus according to claim 19, further comprising one or more optical elements with a splitting function, a magnifying function, a de-magnifying function, a relaying function and/or an imaging function.

29. The apparatus according to claim 19, wherein the beam steering unit comprises two mirror galvanometers forming a two-dimensional scanner unit, the two mirror galvanometers being arranged within a focus plane of a telescope.

30. The apparatus according to claim 19, wherein the beam steering unit comprises a two-dimensional optical phased array forming a two-dimensional scanner unit, the two-dimensional optical phased array being arranged within a focus plane of a telescope.

31. The apparatus according to claim 19,
wherein the beam steering unit comprises a digital light processing element,
wherein the phase modulator comprises a micro lens array, and
wherein the digital light processing element is imaged and magnified on the micro lens array during operation.

32. A method for manufacturing at least two diffractive optical elements, the method comprising:
providing electromagnetic laser radiation;
directing the electromagnetic laser radiation on different locations of a phase modulator with a beam steering unit during a scanning time interval;
imparting a phase profile on the electromagnetic laser radiation with the phase modulator; and
synchronizing a generation of object beam pulses and reference beam pulses with the beam steering unit by a synchronization unit such that no object beam pulses and no reference beam pulses form interference patterns on a photosensitive plate during the scanning time interval,
wherein the scanning time interval being at most 10 millisecond, and
wherein the photosensitive plate comprises a photosensitive material with a chemical reaction time interval larger than a cycle time interval, the cycle time interval comprising the scanning time interval and an recordation time interval.

33. The method according to claim 32, wherein the interference patterns are recorded on the photosensitive plate.

34. The method according to claim 33, wherein at least two of the interference patterns spatially overlap with each other on the photosensitive plate.

35. The method according to claim 32, further comprising:
finishing the at least two diffractive optical elements, wherein at least one interference pattern is comprised by one diffractive optical element.
